(19) United States
(12) Patent Application Publication
(10) Pub. No.: US 2015/0318255 A1
(43) Pub. Date: Nov. 5, 2015

(54) ULTRATHIN MICROELECTRONIC DIE PACKAGES AND METHODS OF FABRICATING THE SAME

(71) Applicants: OMKAR G. KARHADE, Chandler, AZ (US); NITIN A. DESHPANDE, Chandler, AZ (US); DANISH FARUQUI, Chandler, AZ (US)

(72) Inventors: OMKAR G. KARHADE, Chandler, AZ (US); NITIN A. DESHPANDE, Chandler, AZ (US); DANISH FARUQUI, Chandler, AZ (US)

(21) Appl. No.: 14/266,089

(22) Filed: Apr. 30, 2014

(51) Int. Cl. H01L 23/00; H01L 21/306; H01L 23/31; H01L 21/56

(52) U.S. Cl. CPC H01L 24/17; H01L 24/81; H01L 21/563; H01L 21/30604; H01L 23/3157; H01L 2924/10252; H01L 2924/10253; H01L 2924/10271; H01L 2924/1032; H01L 2924/2064; H01L 2224/16113; H01L 2224/16227

(57) ABSTRACT

Ultrathin microelectronic die packages and methods of fabricating the same comprising attaching a microelectronic die to a substrate with a plurality of interconnects, and depositing an underfill material between the microelectronic die and the microelectronic substrate, and around the interconnects. An etchant may be introduced to a back surface of the microelectronic die to remove a portion thereof which reduces the thickness of the microelectronic die to form an ultrathin microelectronic die. In another embodiment, the etching of the microelectronic die forms an ultrathin microelectronic die having a curved surface between the ultrathin microelectronic die back surface and a sidewall thereof.

### TECHNICAL FIELD

Embodiments of the present description generally relate to the field of microelectronic packaging, and, more particularly, to methods of fabricating microelectronic packages with ultrathin microelectronic dice.

### BACKGROUND

The microelectronic industry is continually striving to produce ever faster and smaller microelectronic packages for use in various electronic products, including, but not limited to, computer server products and portable products, such as portable computers, electronic tablets, cellular phones, digital cameras, and the like. As these goals are achieved, the fabrication of the microelectronic packages becomes more challenging. These challenges may relate to reducing the height/thickness of the microelectronic packages, reducing package warpage, eliminating fabrication materials, and the like. One method for overcoming these challenges is through the use of ultrathin microelectronic dice. Ultrathin microelectronic dice are made by forming integrated circuitry for a plurality of microelectronic dice on an active surface of a microelectronic wafer, which can have a thickness of between about 500 μm and 900 μm. The microelectronic wafer is then thinned by removing material from its back surface (i.e. opposing the active surface) to a thickness of about 75 μm or less, such as by grinding, polishing, or ablation. The microelectronic wafer is then diced into individual ultrathin microelectronic dice. As will be understood to those skilled in the art, the use of ultrathin microelectronic dice may offer significant benefits, including, but not limited to, microelectronic package warpage reduction, elimination of materials (such as mold/encapsulation materials), elimination of process steps (such as through via drilling), and the ability to form flexible microelectronic packages. However, preparation and handling of the ultrathin microelectronic dice can be very challenging, as ultrathin microelectronic dice are prone to damage during thinning, dicing, and bonding (during packaging).

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIGS. 1-5 illustrate cross-sectional views of a process of fabricating an ultrathin microelectronic die package, according to an embodiment of the present description.

FIG. 6 is a flow chart of a process of fabricating an ultrathin microelectronic die package, according to an embodiment of the present description.

FIG. 7 illustrates a computing device in accordance with one implementation of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Embodiments of the present description include ultrathin microelectronic die packages and methods of fabricating the same. In one embodiment, a microelectronic die is attached to a microelectronic substrate with a plurality of interconnects, and an underfill material is deposited between the microelectronic die and the microelectronic substrate, and around the interconnects. An etchant may be introduced to a back surface of the microelectronic die may remove a portion thereof which reduces the thickness of the microelectronic die to form an ultrathin microelectronic die. In another embodiment, the etching of the microelectronic die forms an ultrathin microelectronic die having a curved surface between the microelectronic die back surface and a side thereof.

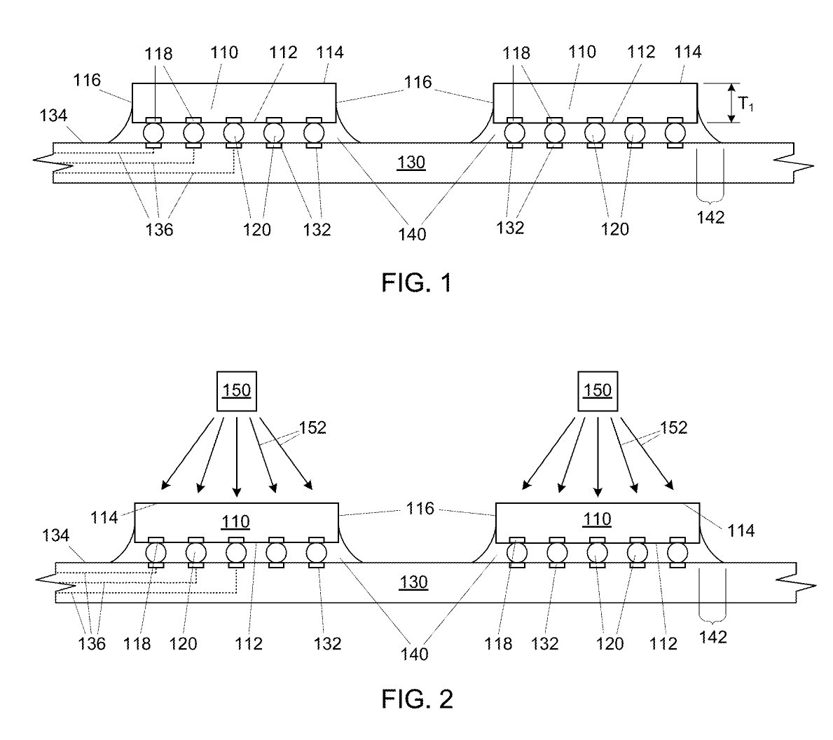

In FIG. 1, a microelectronic die 110, such as a microprocessor, a chipset, a graphics device, a wireless device, a memory device, an application specific integrated circuit, or the like, may be attached to a microelectronic substrate 130, such as an interposer, a motherboard, a flexible substrate, and the like, through a plurality of interconnects 120. The interconnects 120 may extend between bond pads 118 on an active surface 112 of the microelectronic die 110 and mirror-image bond pads 132 on a first surface 134 of the microelectronic substrate 130. The microelectronic die bond pads 118 may be in electrical communication with integrated circuitry (not shown) within the microelectronic die 110. The microelectronic substrate bond pads 132 may be in electrical communication with conductive traces (shown as dashed lines 136) within the microelectronic substrate 130. The conductive traces 136 may provide electrical communication routes between the microelectronic dice 110 on the microelectronic substrate 130 and/or to other components (not shown).

The microelectronic substrate 130 may be primarily composed of any appropriate material, including, but not limited to, liquid crystal polymer, epoxy resin, bismaleimine triazine resin, polybenzoxazole, polyimide material, silica-filled epoxy (such as materials available from Ajinomoto Fine-Techno Co., Inc., 1-2 Suzuki-cho, Kawasaki-ku, Kawasaki-shi, 210-0801, Japan (e.g. Ajinomoto ABF-GX13, and Ajinomoto GX92)), and the like, as well as laminates or multiple layers thereof. The conductive traces 136 may be composed of any conductive material, including but not limited to metals, such as copper, aluminum, nickel, silver, gold, and alloys thereof.

The interconnects 120 can be made any appropriate material, including, but not limited to, solders and conductive filled epoxies. Solder materials may be any appropriate material, including but not limited to, lead/tin alloys, such as 63% tin/37% lead solder, or lead-free solders, such a pure tin or high tin content alloys (e.g. 90% or more tin), such as tin/bismuth, eutectic tin/silver, ternary tin/silver/copper, eutectic tin/copper, and similar alloys. When the microelectronic die 110 is attached to the microelectronic substrate 130 with interconnects 120 made of solder, the solder is reflowed, either by heat, pressure, and/or sonic energy to secure the solder between the microelectronic die bond pads 118 and the microelectronic substrate bond pads 132.

As also shown in FIG. 1, an electrically-insulating underfill material 140 may be disposed between the microelectronic die 110 and the microelectronic substrate 130, and around the interconnects 120. The underfill material 140 may be used to overcome the mechanical stress issues that can arise from thermal expansion mismatch between the microelectronic die 110 and the microelectronic substrate 130, thereby enhancing the reliability of the interconnects 120. The underfill material 140 may be an epoxy material that has sufficiently low viscosity to be wicked between the microelectronic die 110 and the microelectronic substrate 130 by capillary action when introduced by an underfill material dispenser (not shown) along a side 116 of the microelectronic die 110, which will be understood to those skilled in the art. The portion of the underfill material 140 extending past the microelectronic die side 116 is referred to as an underfill material fillet 142. The underfill material 140 may then be subsequently cured (hardened). It will be understood to those skilled in the art that if the microelectronic die 110 were an ultrathin microelectronic die, then disposing the underfill material 140 may be difficult as the underfill material 140 may tend to extend over a back surface 114 (opposing the microelectronic die first surface 112) of the microelectronic die 110.

As shown in FIG. 2, an etchant (shown as arrows 152) may be introduced to the microelectronic die back surface 114. In one embodiment of the present description, the etchant 152 may be a wet etch chemical sprayed by an etchant delivery device 150, such as a spray nozzle or other appropriate device. In one embodiment of the present description, the etchant 152 may be chemical sprayed by an etchant delivery device 150, such as a spray nozzle or other appropriate device. The etchant 152 may be selective to the material of the microelectronic die 110 relative to the material of the microelectronic substrate 130 and the underfill material 140. As will be understood to those skilled in the art, the underfill material fillet 142 may protect the microelectronic die sides 116 from being etched by the etchant 152. In a specific embodiment, the microelectronic die 110 may comprise any appropriate semiconducting material, including but not limited to silicon, germanium, silicon-germanium, and III-V compound semiconductor materials. The etchant may comprise a selective etchant to the specific microelectronic die 110 material and may include, but is not limited to, potassium hydroxide, carbon tetrafluoride, sulfur fluoride, nitric acid/hydrofluoric acid solutions, citric acid/hydrogen peroxide/phosphoric acid solutions, ethylenediamine pyrocatechol, tetramethylammonium hydroxide, and HNA (hydrofluoric acid/nitric acid/acetic acid solutions). In a specific embodiment of the present description, the microelectronic die 110 may be silicon and the etchant may be HNA.

In another embodiment, the etchant 152 may be a plasma of an appropriate gas mixture directed toward the microelectronic die back surface 114 generated by the etchant delivery device 150, such as a radio frequency excitation device. In one embodiment, the gas mixture for the generation of the plasma may include, but is not limited to, carbon tetrafluoride, chlorine, sulfur fluoride, nitrogen trifluoride, and dichlorodifluoromethane.

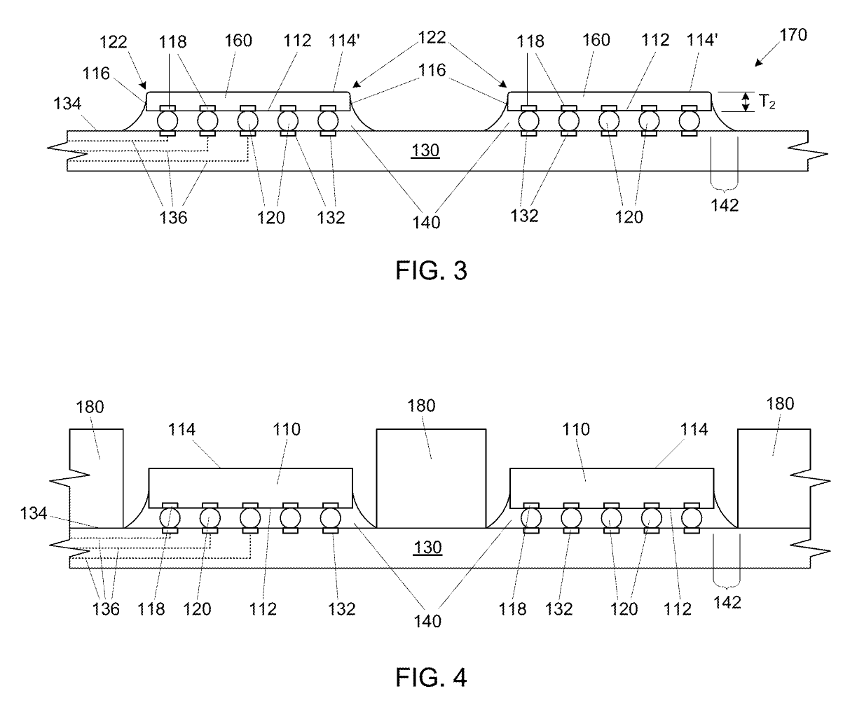

As shown in FIG. 3, the introduction of the etchant 152 may remove a portion of the microelectronic die 110 to reduce a thickness T₁ (see FIG. 1) of the microelectronic die 110, i.e. the distance between the microelectronic die active surface 112 to the microelectronic die back surface 114 (see FIG. 1) to a thickness T₂ to form an ultrathin microelectronic die 160, i.e. the distance between the microelectronic die active surface 112 to a post-etch microelectronic die back surface 114′, thereby forming the ultrathin microelectronic die package 170. In one embodiment the microelectronic die T₁ may be greater than 80 μm. For the purpose of the present description, the ultrathin microelectronic die 160 may be defined to be a microelectronic die having a thickness T₂ of less than about 80 μm and in one embodiment the ultrathin microelectronic die 160 may have a thickness T₂ of less than about 80 μm. In another embodiment, the ultrathin microelectronic die thickness T₂ may be between about 25 μm and less than about 80 μm. In still another embodiment, the ultrathin microelectronic die thickness T₂ may be about 75 μm.

The introduction of the etchant 152 may also result in a curved surface 122 extending between the post-etch microelectronic die back surface 114′ and the at least one microelectronic die side 116. As will be understood to those skilled in the art, the curved surface 122 may alleviate mechanical stress and/or edge effects in the ultrathin microelectronic die 160.

As shown in FIG. 4, although the etchant 152 (see FIG. 2) may be matched for the removal of a portion of the microelectronic die 110, as previously discussed, it may nonetheless damage the microelectronic substrate 130, such as a solder resist layer (not specifically shown) forming the first surface 134 of the microelectronic substrate 130. In one embodiment of the present description, an etch blocking structure 180, such as a jig or a mask, may be placed against exposed areas of the microelectronic substrate first surface 134 prior to etching the microelectronic die 110 to protect the microelectronic substrate 130 from damage by the etchant 152 (see FIG. 2). The etch blocking structure 180 may be any appropriate known structure or material.

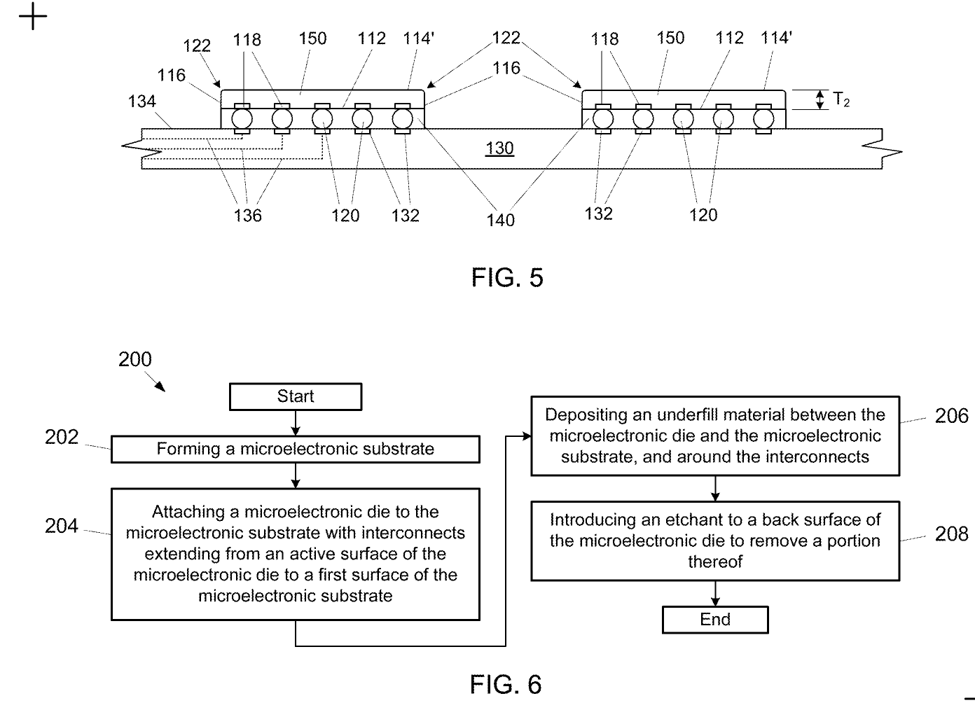

As shown in FIG. 5, if desired, the underfill fillet 142 (see FIG. 1) or the remnants thereof after etching the microelectronic die 110 (see FIG. 1), may be removed. The underfill fillet 142 (see FIG. 1) may be removed by any known technique, including but not limited to grinding with a soft wheel, etching with chemical/plasma treatment, or the like, as will be understood to those skilled in the art.

Embodiments of the present description may have advantages over existing processes. As will be understood to those skilled in the art, warpage of the microelectronic substrate may occur due to thermal expansion mismatch between the microelectronic substrate and the microelectronic dice. This warpage may result non-uniform thinning of the microelectronic dice if a grinding process is used to thin the microelectronic dice. However, with embodiments of the present description, using an etchant to thin the microelectronic dice may result in a uniform thickness regardless of any warpage. Furthermore, as will be understood to those skilled in the art, embodiments of the present description may achieve the benefits of ultrathin microelectronic die packages without the difficulties of handling ultrathin microelectronic dice.

FIG. 6 is a flow chart of a process 200 of fabricating an ultrathin microelectronic package according to an embodiment of the present description. As set forth in block 202, a microelectronic substrate may be formed. A microelectronic die may be attached to the microelectronic substrate with interconnects extending from an active surface of the microelectronic die to a first surface of the microelectronic substrate, as set forth in block 204. As set forth in block 206, an underfill material may be deposited between the microelectronic die and the microelectronic substrate, and around the interconnects. An etchant may be introduced to a back surface of the microelectronic die may remove a portion thereof which reduces the thickness of the microelectronic die to form an ultrathin microelectronic die, as set forth in block 208.

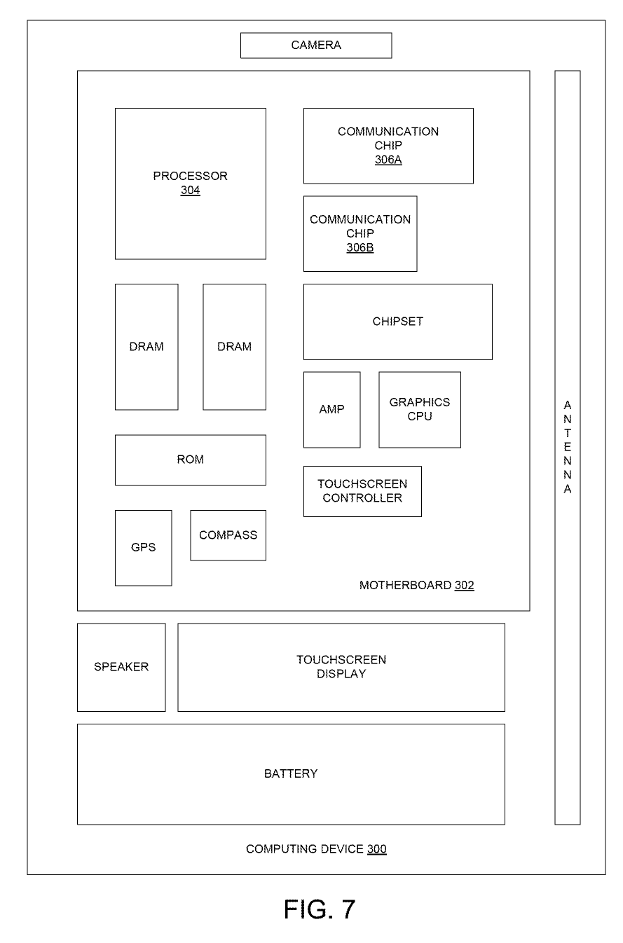

FIG. 7 illustrates a computing device 300 in accordance with one implementation of the present description. The computing device 300 houses a board 302. The board 302 may include a number of components, including but not limited to a processor 304 and at least one communication chip 306A, 306B. The processor 304 is physically and electrically coupled to the board 302. In some implementations the at least one communication chip 306A, 306B is also physically and electrically coupled to the board 302. In further implementations, the communication chip 306A, 306B is part of the processor 304.

Depending on its applications, the computing device 300 may include other components that may or may not be physically and electrically coupled to the board 302. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 306A, 306B enables wireless communications for the transfer of data to and from the computing device 300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 306 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 300 may include a plurality of communication chips 306A, 306B. For instance, a first communication chip 306A may be dedicated to shorter range wireless communications such as Wi-Fi and Bluetooth and a second communication chip 306B may be dedicated to longer range wireless communications such as GPS, EDGE, GPRS, CDMA, WiMAX, LTE, Ev-DO, and others.

The processor 304 of the computing device 300 may include a microelectronic package having an ultrathin microelectronic die fabricated in the manner described above. The term “processor” may refer to any device or portion of a device that processes electronic data from registers and/or memory to transform that electronic data into other electronic data that may be stored in registers and/or memory.

The communication chip 306A, 306B may include a microelectronic package having a microelectronic package having an ultrathin microelectronic die fabricated in the manner described above.

In various implementations, the computing device 300 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 300 may be any other electronic device that processes data.

It is understood that the subject matter of the present description is not necessarily limited to specific applications illustrated in FIGS. 1-7. The subject matter may be applied to other microelectronic devices and assembly applications, as well as any appropriate electronic application, as will be understood to those skilled in the art.

The following examples pertain to further embodiments. Specifics in the examples may be used anywhere in one or more embodiments.

In Example 1, a method of fabricating an ultrathin microelectronic package may comprise forming a microelectronic substrate having a first surface, attaching a microelectronic die to the microelectronic substrate with interconnects extending from a first surface of the microelectronic die to the microelectronic substrate first surface, depositing an underfill material between the microelectronic die and the microelectronic substrate, and around the interconnects, and introducing an etchant to a back surface of the microelectronic die to remove a portion thereof.

In Example 2, the subject matter of Example 1 can optionally include introducing the etchant to the microelectronic die back surface to remove the portion thereof forming a curved surface extending between the microelectronic die back surface and the at least one microelectronic die side.

In Example 3, the subject matter of Example 1 or 2 can optionally include introducing the etchant to the microelectronic die back surface to remove the portion thereof comprising introducing a wet chemical etchant selected from the group consisting essentially of potassium hydroxide, carbon tetrafluoride, sulfur fluoride, nitric acid/hydrofluoric acid solutions, citric acid/hydrogen peroxide/phosphoric acid solutions, ethylenediamine pyrocatechol, tetramethylammonium hydroxide, and hydrofluoric acid/nitric acid/acetic acid solutions.

In Example 4, the subject matter of any of Examples 1 to 3 can optionally include introducing the etchant to the microelectronic die back surface to remove the portion thereof comprising introducing a hydrofluoric acid/nitric acid/acetic acid solution to the microelectronic die back surface, wherein the microelectronic die is formed from silicon.

In Example 5, the subject matter of any of Examples 1 to 4 can optionally include introducing the etchant to the microelectronic die back surface to remove the portion thereof comprising introducing a plasma etchant formed from a gas selected from the group consisting essentially of carbon tetrafluoride, chlorine, sulfur fluoride, nitrogen trifluoride, and dichlorodifluoromethane.

In Example 6, the subject matter of any of Examples 1 to 5 can optionally include attaching the microelectronic substrate to the microelectronic substrate comprising attaching microelectronic die formed from a material selected from the group consisting essentially of silicon, germanium, silicon-germanium, and III-V compound semiconductor materials.

In Example 7, the subject matter of any of Examples 1 to 6 can optionally include introducing the etchant to the microelectronic die back surface to thin the microelectronic die to a thickness less than about 80 μm.

In Example 8, the subject matter of any of Examples 1 to 7 can optionally include introducing the etchant to the microelectronic die back surface to thin the microelectronic die to a thickness of between about 70 μm and less than about 80 μm.

In Example 9, the subject matter of any of Examples 1 to 8 can optionally include introducing the etchant to the microelectronic die back surface to thin the microelectronic die to a thickness of about 75 μm.

In Example 10, the subject matter of any of Examples 1 to 9 can optionally include removing a fillet portion of the underfill material.

In Example 11, the subject matter of any of Examples 1 to 10 can optionally include placing an etch blocking structure on exposed areas of the microelectronic substrate first surface prior to etching the microelectronic die.

In Example 12, a microelectronic package may comprising a microelectronic substrate, a microelectronic die including a first surface, a second surface, and at least one side, wherein the microelectronic die is attached to the microelectronic substrate with interconnects extending from a first surface of the microelectronic die to the microelectronic substrate first surface, and wherein the microelectronic die includes a curved surface extending between microelectronic die back surface and the at least one microelectronic die side, and a thickness defined by the distance between the microelectronic die first surface and the microelectronic die second surface; and an underfill material between the microelectronic die and the microelectronic substrate, and around the interconnects.

In Example 13, the subject matter of Example 12 can optionally include the microelectronic die thickness being less than about 80 μm.

In Example 14, the subject matter of Example 12 or 13 can optionally include the micronelectronic die thickness being between about 70 μm and less than about 80 μm.

In Example 15, the subject matter of any of Examples 12 to 14 can optionally include the microelectronic die thickness being about 75 μm.

In Example 16, a computing device may comprises a board and a microelectronic package attached to the board, comprising a microelectronic substrate, a microelectronic die including a first surface, a second surface, and at least one side, wherein the microelectronic die is attached to the microelectronic substrate with interconnects extending from a first surface of the microelectronic die to the microelectronic substrate first surface, and wherein the microelectronic die includes a curved surface extending between microelectronic die back surface and the at least one microelectronic die side, and a thickness defined by the distance between the microelectronic die first surface and the microelectronic die second surface, and an underfill material between the microelectronic die and the microelectronic substrate, and around the interconnects.

In Example 17, the subject matter of Example 16 can optionally include the microelectronic die thickness being less than about 80 μm.

In Example 18, the subject matter of Example 16 or 17 can optionally include the microelectronic die thickness being between about 25 μm and less than about 80 μm.

In Example 19, the subject matter of any of Examples 16 to 18 can optionally include the microelectronic die thickness being about 75 μm.

Having thus described in detail embodiments of the present description, it is understood that the present description defined by the appended claims is not to be limited by particular details set forth in the above description, as many apparent variations thereof are possible without departing from the spirit or scope thereof.

1. A method of fabricating an ultrathin microelectronic package, comprising:
forming a microelectronic substrate having a first surface;
attaching a microelectronic die to the microelectronic substrate with interconnects extending from a first surface of the microelectronic die to the microelectronic substrate first surface;
depositing an underfill material between the microelectronic die and the microelectronic substrate, and around the interconnects; and
introducing an etchant to a back surface of the microelectronic die to remove a portion thereof.

2. The method of claim 1 wherein introducing the etchant to the microelectronic die back surface to remove the portion thereof forms a curved surface extending between the microelectronic die back surface and the at least one microelectronic die side.

3. The method of claim 1 wherein introducing the etchant to the microelectronic die back surface to remove the portion thereof comprises introducing a wet chemical etchant selected from the group consisting essentially of potassium hydroxide, carbon tetrafluoride, sulfur fluoride, nitric acid/hydrofluoric acid solutions, citric acid/hydrogen peroxide/phosphoric acid solutions, ethylenediamine pyrocatechol, tetramethylammonium hydroxide, and hydrofluoric acid/nitric acid/acetic acid solutions.

4. The method of claim 1 wherein introducing the etchant to the microelectronic die back surface to remove the portion thereof comprises introducing a hydrofluoric acid/nitric acid/acetic acid solution to the microelectronic die back surface, wherein the microelectronic die is formed from silicon.

5. The method of claim 1 wherein introducing the etchant to the microelectronic die back surface to remove the portion thereof comprises introducing a plasma etchant formed from a gas selected from the group consisting essentially of carbon tetrafluoride, chlorine, sulfur fluoride, nitrogen trifluoride, and dichlorodifluoromethane.

6. The method of claim 1 wherein attaching a microelectronic substrate to the microelectronic substrate comprises attaching microelectronic die formed from a material selected from the group consisting essentially of silicon, germanium, silicon-germanium, and III-V compound semiconductor materials.

7. The method of claim 1 wherein introducing the etchant to the microelectronic die back surface to remove the portion thereof comprises introducing the etchant to the microelectronic die back surface to thin the microelectronic die to a thickness less than about 80 μm.

8. The method of claim 7 wherein introducing the etchant to the microelectronic die back surface to thin the microelectronic die to a thickness less than about 80 μm comprises introducing the etchant to the microelectronic die back surface to thin the microelectronic die to a thickness of between about 25 μm and less than about 80 μm.

9. The method of claim 8 wherein introducing the etchant to the microelectronic die back surface to thin the microelectronic die to a thickness of between about 70 μm and less than about 80 μm comprises introducing the etchant to the microelectronic die back surface to thin the microelectronic die to a thickness of about 75 μm.

10. The method of claim 1, further including removing a fillet portion of the underfill material.

11. The method of claim 1, further including placing an etch blocking structure on exposed areas of the microelectronic substrate first surface prior to etching the microelectronic die.

12.-19. (canceled)

20. A method of fabricating an ultrathin microelectronic package, comprising:
forming a microelectronic substrate having a first surface;
attaching a plurality of microelectronic dice to the microelectronic substrate, wherein each microelectronic die of the plurality of microelectronic dice include interconnects extending from a first surface of each of the plurality of the microelectronic die to the microelectronic substrate first surface;
depositing an underfill material between each microelectronic die of the plurality of microelectronic dice and the microelectronic substrate, and around the interconnects; and
introducing an etchant to a back surface of each microelectronic die of the plurality of microelectronic dice to remove a portion thereof.

21. The method of claim 20 wherein introducing the etchant to the die back surface of each of the microelectronic die of the plurality of microelectronic dice to remove the portion thereof forms a curved surface extending between each microelectronic die back surface and the at least one microelectronic die side of each microelectronic die of the plurality of microelectronic dice.

22. The method of claim 20 wherein introducing the etchant to the microelectronic die back surface to thin the microelectronic die to a thickness less than about 80 μm comprises introducing the etchant to the microelectronic die back surface to thin the microelectronic die to a thickness of between about 25 μm and less than about 80 μm.

23. The method of claim 20, further including removing a fillet portion of the underfill material.

24. The method of claim 20, further including placing an etch blocking structure on exposed areas of the microelectronic substrate first surface prior to etching the microelectronic die.

25. A method of fabricating an ultrathin microelectronic package, comprising:
forming a microelectronic substrate having a first surface;
attaching a plurality of microelectronic dice to the microelectronic substrate, wherein each microelectronic die of the plurality of microelectronic dice include interconnects extending from a first surface of each of the plurality of the microelectronic die to the microelectronic substrate first surface;
depositing an underfill material between each microelectronic die of the plurality of microelectronic dice and the microelectronic substrate, and around the interconnects;
placing an etch blocking structure on exposed areas of the microelectronic substrate first surface prior to etching the microelectronic die;
introducing an etchant to a back surface of each microelectronic die of the plurality of microelectronic dice to remove a portion thereof; and
removing a fillet portion of the underfill material.

26. The method of claim 25 wherein introducing the etchant to the die back surface of each of the microelectronic die of the plurality of microelectronic dice to remove the portion thereof forms a curved surface extending between each microelectronic die back surface and the at least one microelectronic die side of each microelectronic die of the plurality of microelectronic dice.

27. The method of claim 25 wherein introducing the etchant to the microelectronic die back surface to thin the microelectronic die to a thickness less than about 80 μm comprises introducing the etchant to the microelectronic die back surface to thin the microelectronic die to a thickness of between about 25 μm and less than about 80 μm.
